(19) United States
(12) Patent Application Publication
(10) Pub. No.: US 2001/0039082 A1
(43) Pub. Date: Nov. 8, 2001

(54) Solar cell

(76) Inventors: Gerhard Strobl, Stuttgart (DE); Karlheinz Tentscher, Heilbronn (DE); Paul Uebele, Untergruppenbach (DE)

Correspondence Address: DENNISON, SCHEINER, SCHULTZ & WAKEMAN, 1745 Jefferson Davis Highway, Suite 612, Arlington, VA, 22202, US

(21) Appl. No.: 09/825,358

(22) Filed: Apr. 4, 2001

(30) Foreign Application Priority Data
Apr. 6, 2000 (DE) 100 16 972.4

(51) Int. Cl. H01L 21/337

(52) U.S. Cl. 438/189

(57) ABSTRACT

The present invention relates to a solar cell (10) comprising a semiconductor body (12) having an n⁺p junction. In order that the solar cell exhibits a good EOL behavior, it is proposed that the solar cell (10) comprise first and second areas (28, 30, 32, 34, 48) having differing thicknesses (d₁, d₂), the first area (28, 30, 48) forming a support structure of the solar cell and the second area (32, 34) having a considerably lower thickness than the first area.

The present invention relates to a solar cell, comprising a semiconductor substrate in which charge carriers may be produced by means of incident radiation energy, said charge carriers being able to be separated by means of an electrical field and then to be conducted off by means of electrically conductive terminals, in particular comprising a semiconductor body having an nip junction, preferably having a back surface field (BSF), partially formed if necessary, the solar cell comprising first and second areas of different thickness, the first area forming a support structure of the solar cell and the second area having a thickness which is considerably less than the first area.

Apart from optimally coupling the light by suitable surface structuring and terminal arrangement, an essential precondition for achieving high efficiency in photovoltaic solar cells is in particular a contact surface that is as small as possible and a very good surface passivation in the active area of the semiconductor. To optimally utilize the radiation energy incident on the solar cell, a reflector layer may be deposited on the back of the structure, where a so-called back surface field (BSF) may be provided to avoid high recombination speeds. It is possible to either provide the whole of the back surface with a BSF or to only partially cover the back surface with a BSF, according to German Patent DE 38 15 512 C2. This is done in the case of a solar cell with n⁺p structure by arranging an insulating layer between the whole of the semiconductor substrate and the back surface contact layer, the insulating layer being provided with openings for forming an ohmic contact between the semiconductor substrate and the contact layer, where highly doped p⁺ zones are formed, extending from the openings into the semiconductor substrate By combining the partial p⁺-type doping with the insulating layer consisting of highly pure oxide, silicon oxide or silicon oxinitride, an effect is achieved comparable to a p⁺ zone covering the whole of the structure, so that charge carrier recombination is negligible.

In space, solar cells are exposed to high energy electron, proton and other radiation, diminishing their performance. At the beginning of the mission, their performance is up to their beginning-of-life (BOL) performance while, after a certain period of time, it is down to their end-of-life (EOL) performance.

To achieve a good end-of-life behavior, thin solar cells are preferred, since they show good efficiency characteristics regardless of a low diffusion length caused by radiation damage. A drawback of such thin solar cells is their mechanical instability and the difficulty, bordering on the impossible, of treating or processing them.

A solar cell of the type mentioned at the outset is disclosed in U.S. Pat. No. 3,802,924. In order to reduce the weight of such a solar cell, it comprises a circumferential rim having a thickness of between 200 and 300 μm and a width of between 1 and 2 mm. The thickness of the solar cell in the area surrounded by the rim is about 100 μm. The cells themselves have dimensions of 2×2 cm², 2×4 cm². 3×4 cm² and 2×6 cm², which makes them relatively small in surface area.

The object underlying the present invention is to further develop a solar cell of the above-mentioned type, in particular comprising an n⁺p junction, as well as a p⁺ back surface field, partially formed if necessary, in such a way that the desired solar cell can be provided of a thickness having good EOL behavior without considerable loss in mechanical stability and treatment I processing behavior.

In accordance with the invention, the problem is solved substantially by providing the solar cell with recesses extending from the back surface and forming the second area, circumferentially defined by sections of the first area, the first area having a thickness d₁, where d₁≦80 μm, the second area having a thickness d₂, where 20 μm ≦d₂≦80 μm, the ratio of the thickness d₁ of the first area and the thickness d₂ of the second area being d₁/d₂≦1.2. In particular, d₁ is about 100 to 150 μm, preferably 130 μm, while d₂ is about 40 to 60 μm, preferably 50 μm.

In accordance with the invention, a solar cell is provided that is locally “thinned” in certain areas. This means that areas essentially not having support functions are mechanically very fragile whereas other areas provide the mechanical stability required for handling the solar cell. In particular, the ratio of the surface area F₁ of the first areas and the surface area F₂ of the second areas is 1:40≦F₁:F₂≦1:3, with the surface ratio being determined in a plane defined by exposed outer surfaces of the second areas. The areas having greater density are not only in the circumferential area, but are formed as crisscrossing webs.

Preferably recesses extend from the back surface of the solar cell, having between them the first support areas. The recesses resulting in localized thinning of the solar cell may be formed as trenches and/or truncated-pyramid bases and/or truncated-cone bases and/or spherical sections.

Therefore, the solar cell in accordance with the invention may be arranged, for example by adhesion, on the first areas protruding over the second areas, the hollow spaces between the second areas and the support surfaces of the first areas being able to be filled with a material of a density that is lower than that of the solar cell. In particular, the areas may be filled with an adhesive or with an adhesive and micro balloons. This enhances the overall stability of the solar cell whose overall weight is however considerably lower than that of the structure of a conventional solar cell, in which the solar cell is mechanically stable over the whole of its surface, i,e. essentially having an even thickness. An advantage of a solar cell of the above-mentioned type is therefore that the solar cell comprises recesses forming the second area in its back surface, circumferentially defined by sections of the first areas, and that the recesses are at least partially filled in using a material whose specific density is lower than that of the solar cell.

The recesses in the solar cell are themselves defined by webs forming an angle α to the normal of the solar cell, where 0°≦α≦60°, and in particular α≦40°.

Moreover, it is provided that the solar cell is joined, for example by soldering or welding, with terminals leading for example to further solar cells, situated in the direction of a projection of the exposed support surfaces of the first areas in the normal direction of the solar cell.

The surface not having the recesses, i.e. in particular the front surface of the solar cell can be smooth or can be structured for example by recesses or protrusions in the form of truncated-pyramid bases. It is also possible to form the front surface semiconductor layer, i.e., in the case of an n⁺p structure the emitter, to comprise integrated diodes, which means an n⁺/p⁺ junction is formed in a planar emitter (p-n transmission) working as a Zener diode when the solar cell is being used in reverse operation Reference is made to well-known circuitry.

Further details, advantages and features of the invention can be seen not only from the claims and the features to be derived from them—singly and/or in combination—but also from the following description of the preferred embodiment taken in conjunction with the accompanying drawing, in which:

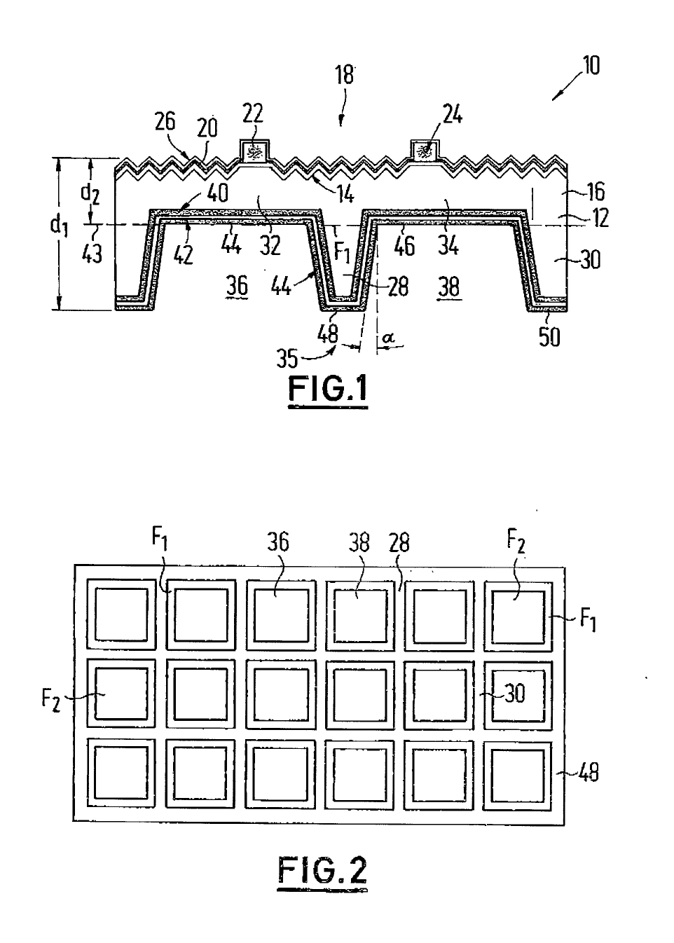

FIG. 1 shows a sectional view of a portion of a solar cell in accordance with the invention.

FIG. 2 shows a bottom view of a solar cell.

FIG. 1 shows a solar cell 10 in accordance with the invention, having a semiconductor substrate or body 12 comprising an n⁺ area 14 at the front forming the emitter and a p doped area 16, so that an n⁺p junction is formed extending from the front of the solar cell 10. A passivating layer 20 of for example SiO₂. CVD SiO₂, silicon nitride or a double layer of SiO₂ and Si₃N₄, is deposited, preferably plasma deposited, on the n⁺ area. As is well known, strip like front terminals 22, 24, for example made of titanium palladium silver, run along the surface of the n⁺ layer 14 stripped of the passivating layer 20. The passivating layer 20 as well as the terminals 22, 24 can be covered by an anti-reflecting layer 26.

As illustrated in the diagram of FIG. 1, the front surface, i.e. the emitter surface of the solar cell, can be structured, namely by wave-like or pyramid-like structures. Reference is however made to well known designs in this respect.

To realize the advantages of a very thin solar cell without losses of mechanical stability and hence handling properties, the solar cell 10 in accordance with the invention is made very thin in some areas, i.e. it is locally “thinned”. This means that the solar cell comprises first areas 28, 30 ensuring mechanical stability and second very thin areas 32, 34. To do so, areas 36. 38 are etched using conventional masking techniques into the back surface 35 of the solar cell 10 of the embodiment shown. The etching process of the areas 36, 38 can be performed before formation of the front surface 18.

After local “thinning” of the solar cell 10, i.e. formation of the areas 32, 34 defined by the recesses, the back surface layers are made, with a back surface field (BSF) being formed on the back surface 35, preferably covering the whole of the back surface or, if necessary, forming a partial back surface field as described in German Patent Specification DE 36 15 512 C2. Reference is made to said disclosure. This means that on the back surface of the substrate 12 a p⁺ zone 40 is formed, for example by boron diffusion, boron implantation or using an aluminum alloy, on which the following successive layers are deposited using well-known techniques: a passivating layer having holes, for example consisting of an oxide, an aluminum reflecting layer 42, and then a back surface contacting layer 44 for example comprising the following succession of layers: aluminum—titanium—palladium—silver.

The areas not etched away, i.e. the areas 28, 30 forming protrusions, afford the necessary mechanical stability of the solar cell 10, whereas the very thin areas 32, 34 ensure the desired good EOL behavior of the solar cell 10.

Such recesses 36, 38 can have any desired geometry, such as for example in the form of trenches, truncated-pyramid or truncated-cone or spherical sections. The webs 28, 30 defining the recesses 36, 38 can taper towards their free ends and can form an angle α to the normal of the solar cell 10 where preferably α≦45°.

The first areas 28, 30 ensuring mechanical stability extending to the front surface of the solar cell 10 can have a thickness d₁ in the order of between 80 and 200 μm, preferably in the order of 130 μm, while the thin areas 32, 34 have a thickness in the order of between 20 and 80 μm, preferably in the order of 50 μm. The ratio of the densities is in particular 2.5≧d₁/d₂≧1.2, where d₂ is between 20 and 80 μm.

The ratio of the surface areas of the first areas (F₁) to the second areas (F₂) in a plane defined by the bottom surfaces 44, 46 of the recesses 36, 38 should be 1:40≦F₁:F₂≦1:3.

The solar cell 10 will be supported, and affixed if necessary, on a carrier using its first areas 28, 30, i.e. its exposed outer surfaces 48, 50. The exposed areas of the recesses 36, 38, i.e. between the apparent protrusions 28, 30, can also be filled in using an adhesive material and/or using an adhesive material and micro balloons (small globules formed of a thin plastic skin and filled with air). This affords additional mechanical stability to the solar cell 10. The solar cell 10 according to the present embodiment of the invention has however has a considerable weight advantage over solid cells.

FIG. 2 is a diagrammatic bottom view of a solar cell 10 in accordance with the invention where the recesses 36, 38 are in the form of truncated pyramids. The first areas ensuring mechanical stability are formed by crisscrossed webs 28, 30 as well as by a circumferential rim 48 on the back surface.

Typical surface extensions of a solar cell in accordance with the invention are for example the nominal dimensions of 4 cm×6 cm when using silicon wafers with a diameter of 100 mm.

1. A solar cell (10) comprising a semiconductor substrate, in which charge carriers can be produced by incident radiation energy, said charge carriers being able to be separated and then to be conducted off via conductive terminals (22, 24, 44), in particular comprising a semiconductor body (12) having an n⁺p junction, preferably having a back surface field (BSF) on its back surface, partially formed if necessary, said solar cell comprising first and second areas (28, 30, 32, 34 48) of differing thicknesses (d₁, d₂), said first area (28, 30, 48) forming a support structure of the solar cell and said second area (32, 34) having a considerably lower thickness than the first area,
wherein
the solar cell (10) has recesses (36, 38) extending from its back surface (35) forming the second area and circumferentially defined by sections of the first area (28, 30), wherein the first area (28, 30, 48) has a thickness d₁, where d₁≧80 μm, and the second area (32, 34) has a thickness d₂, where 20 μm≦d₂≦80 μm, the ratio of the thickness d₁ of the first area to the thickness d₂ of the second area being d₁/d₂≧1.2.

2. A solar cell according to claim 1,
wherein
the first area (28, 30, 48) has a thickness d₁, where 100 μm≦d₁≦150 μm, and/or the second area (32, 34) has a thickness d₂, where 40 μm≦d₂≦60 μm.

3. A solar cell according to claim 1,
wherein
the solar cell (10) comprises a plurality of recesses (36, 38) extending from its back surface (35) circumferentially defined by sections of the first areas (28, 30).

4. A solar cell according to claim 3,
wherein
the recesses (36, 38) are in the form of trenches, truncated pyramids, truncated cones or spherical sections.

5. A solar cell according to claim 1,
wherein
the solar cell (10) may be supported, and affixed if necessary, on a carder using the first areas (28, 30) or its exposed bottom surfaces (48, 50).

6. A solar cell according to claim 1
wherein
the recesses (36, 38) are at least partially filled in using a material whose specific density is lower than the density of the solar cell (10).

7. A solar cell according to claim 6,
wherein
the recesses (36, 38) are filled in using an adhesive material and/or an adhesive material and micro balloons.

8. A solar cell according to claim 3,
wherein
the recesses (36, 38) are defined by webs forming the sections (28, 30) of the first area forming an angle α to the normal of the solar cell (10), where 0°≦α≦60°, and in particular α≦40°.

9. A solar cell according to claim 3,
wherein
in a plane (43) defined by the bottom surfaces (44, 46) of the recesses (36, 38) the first areas (28, 30) have a surface extension F₁ and the second areas (32, 34) have a surface extension F₂, where in particular 1:40≦F₁:F₂≦1:3.

10. A solar cell (10) comprising a semiconductor substrate able to produce charge carriers using incident radiation energy, which charge carriers can be separated by means of an electrical field and then conducted off using electrically conductive terminals (22, 24, 44), in particular comprising a semiconductor body (12) having an nip junction, preferably having a back surface field (BSF), partially formed if necessary, on its back surface, the solar cell comprising first and second areas (28, 30, 32, 34, 48) having differing thicknesses (d1, d2), said first area (28, 30, 48) forming a support structure of the solar cell and said second area (32, 34) having a considerably lower thickness than the first area,
wherein
the solar cell (10) has recesses (36, 38) extending from its back surface (35) forming the second area and circumferentially defined by sections of the first areas (28, 30) and wherein the recesses are at least partially filled in using a material whose specific density is lower than the density of the solar cell (10)
